(19) United States
(12) Patent Application Publication
(10) Pub. No.: US 2005/0112481 A1
(43) Pub. Date: May 26, 2005

(54) Exposure method and apparatus

(75) Inventor: Michihiro Hirooka, Utsunomiya-shi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/390,766

(22) Filed: Mar. 19, 2003

(30) Foreign Application Priority Data
Mar. 20, 2002 (JP) 2002-077476

(51) Int. Cl. G03F 7/20

(52) U.S. Cl. 430/30; 430/322; 355/18

(57) ABSTRACT

An exposure method for exposing a pattern image on a reticle onto a plate through a projection optical system by synchronously scanning the reticle and the plate includes measuring a surface shape of the reticle at a position to be exposed and holding the surface shape as correction data, controlling the synchronous scan based on the correction data, and updating the correction data by repeating measurements of the surface shape of the reticle.

### BACKGROUND OF THE INVENTION

The present invention relates generally to projection exposure methods and apparatuses used to expose a pattern on a reticle or mask (these terms are used interchangeably in this application) onto a plate, such as a wafer in a lithography process to fabricate, for example, semiconductor devices, liquid crystal display devices etc.

Scan-type, e.g., step-and-scan type projection exposure apparatuses (referred to as “scanners”) have been used to fabricate semiconductor devices, etc. as well as collective exposure type exposure apparatuses, such as steppers. A projection optical system in such a projection exposure apparatus has been required for almost limit resolution, and thus includes a mechanism for measuring resolution affecting factors (such as atmospheric pressure, ambient temperature, etc.) and for correcting imaging performance based on the measurement result. In addition, since a large numerical aperture, which it sets for higher resolution, consequently shortens a depth of focus, it further includes an autofocus mechanism for measuring a focus position on a rough surface on a wafer as a plate in an optical-axis direction of the projection optical system, using a focus position detection system of an oblique incidence system, and for according the wafer surface with an image plane of the projection optical system based on the measurement result.

However, an imaging error due to a deformation of a reticle has recently become non-negligible gradually. For example, if a pattern surface on a reticle deflects towards the projection optical system almost uniformly, an average position of an image plane lowers and tends to generate a defocus. In addition, a deformed pattern surface on the reticle possibly changes a pattern position on the pattern surface in a direction horizontal to an optical axis of the projection optical system. Such a lateral offset causes a distortion error.

Factors that would deform a reticle include (a) a deformation due to its own weight, (b) the flatness of a reticle pattern, and (c) a deformation due to the flatness of a contact surface of a reticle holder that absorbs and holds the reticle, e.g., dust between the reticle and the contact surface. The deformation amounts resulting from these factors have been unable to be ignored. A state of the deformation differs according to reticles and according to reticle holders in exposure apparatuses. Therefore, a precise measurement of a deformation amount of a reticle needs the measurement to be conducted while the reticle is actually absorbed and held on a reticle holder in a projection exposure apparatus.

Conceivably, one method for measuring the reticle's pattern and for correcting an optical characteristic of the projection optical system or a position of a wafer relative to the projection optical system is to detect a reticle's pattern surface in front of the exposure light during a scan exposure and provide a real-time correction. However, a realization of this scheme would disadvantageously increase a cost of a processing system since it requires high-speed calculations of correction values based on measurement values of the reticle's pattern surface during scan exposure.

It is also conceivable to measure the reticle's pattern surface in advance to exposure and to previously calculate and hold it as a correction value of an optical characteristic of a projection optical system or a position of a wafer relative to the projection optical system. Nevertheless, this cannot provide an adequate correction since the reticle would result in a thermal deformation due to absorption of the illumination light after an exposure starts.

### BRIEF SUMMARY OF THE INVENTION

Accordingly, it is an exemplified object of the present invention to provide an exposure method and apparatus, which easily improve reliability of a correction to an optical characteristic of a projection optical system, or a position of a wafer relative to the projection optical system.

An exposure method of one aspect of the present invention for exposing a pattern image formed on a reticle onto a plate through a projection optical system by synchronously scanning the reticle and the plate includes the steps of measuring a surface shape of the reticle at a position to be exposed, and holding the surface shape as correction data, controlling a synchronous scan based on the correction data, and updating the correction data by repeating measurements of the surface shape of the reticle.

The controlling step may correct an optical characteristic of the projection optical system. The controlling step may correct a position of the plate relative to the projection optical system. The updating step may measure the surface shape of the reticle during exposure. The updating step may update the correction data whenever an exposure for one shot ends. The measuring and holding step may measure the surface shape of the reticle at a position to be exposed in a scan direction. The measuring and holding step may prepare the correction data from an average of plural measurements that have been conducted at position to be exposed. The measuring and holding step may measure plural times at the same speed and in the same direction. The surface shape of the reticle may be measured by measuring a pattern surface of the reticle relative to the projection optical system.

An exposure apparatus of another aspect of the present invention for exposing a pattern image on a reticle onto a plate by synchronously scanning the reticle and the plate includes a projection optical system that projects the pattern image onto the plate, a measurement unit for measuring a surface shape of the reticle at a position to be exposed and for holding the surface shape as correction data, the measurement unit updating the correction data by repeating measurements of the surface shape of the reticle, and a controller for controlling the synchronous scan based on the correction data.

A device fabrication method of still another aspect of the present invention includes the steps of exposing a pattern on a reticle, onto an object by using the above exposure apparatus, and performing a predetermined process fox the exposed object. Claims for the device fabrication method that exhibits operations similar to those of the above exposure apparatus cover devices as their intermediate products and finished products. Moreover, such devices include semiconductor chips such as LSIs and VLSIs, CCDs, LCDs, magnetic sensors, thin-film magnetic heads, etc.

Other objects and further features of the present invention will become readily apparent from the following description of the embodiments with reference to accompanying drawings.

### BRIEF DESCRIPTION OF THE DRAWINGS

FIG. 1 is a flowchart of an exposure apparatus of a first embodiment according to the present invention.

FIG. 2 is a flowchart of an exposure apparatus of a second embodiment according to the present invention.

FIG. 3 is a schematic sectional view of an exposure apparatus according to the present invention.

FIG. 4 is a schematic sectional view for explaining a measurement system for measuring a reticle surface position.

FIG. 5 is a flowchart for explaining a device fabrication method according to the present invention.

FIG. 6 is a flowchart for explaining a device fabrication method according to the present invention.

### DETAILED DESCRIPTION OF THE PREFERRED EMBODIMENTS

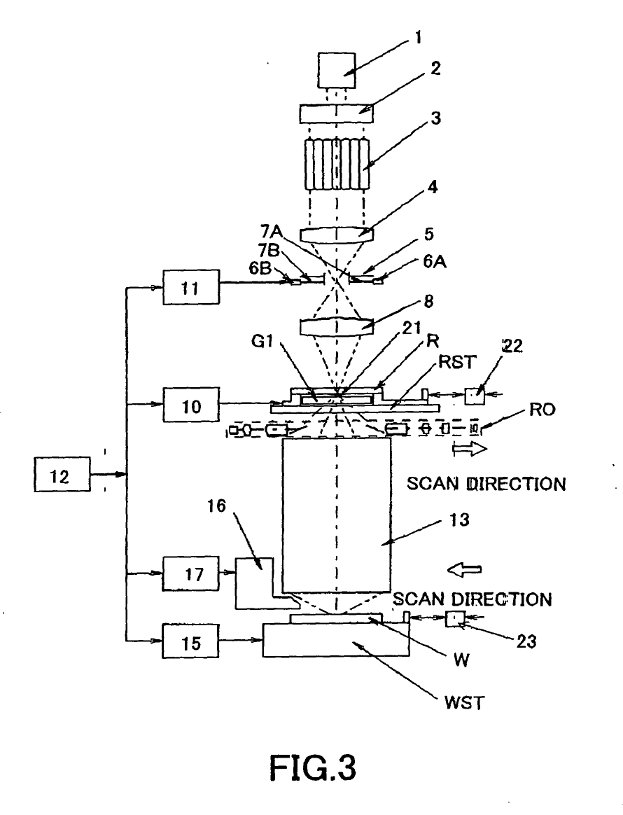

A detailed description will now be given of the embodiments according to the present invention. FIG. 3 shows a partial schematic view of a projection exposure apparatus of a slit scan manner using a scan exposure method according to the present invention.

In FIG. 3, a rectangular slit shaped illumination area 21 on a reticle R is illuminated with a uniform light intensity by a light source 1 and an illumination optical system including an illumination-light shaping optical system 2 to relay lens 8, and a circuit pattern image on the reticle R in the slit shaped illumination area 21 is transferred onto the wafer W through the projection optical system 13. The light source 1 may include a pulse light source including an excimer laser light source, such as an F₂ excimer laser, ArF excimer laser, and a KrF excimer laser, a metal vapor laser, a harmonic generation device, such as a YAG laser, and a continuous light source, such as a mercury lamp and an ellipsoidal mirror.

The pulse light source switches on and off exposure under control of supply power from a power supply unit for the pulse light source, whereas the continuous light source switches on and off exposure using a shutter in the illumination-light shaping optical system 2. The instant embodiment has a mobile blind or variable field stop 7 as described later, and thus may switch exposure by opening and closing the variable blind 7.

In FIG. 3, a beam diameter of the illumination light from the light source is set to a predetermined size by the illumination-light shaping optical system 2, and the illumination light reaches the fly-eye lens 3. An exit surface of the fly-eye lens 3 forms multiple secondary light sources. The illumination-light from these secondary light sources are condensed by the condenser lens 4 and reaches the mobile blind or variable field stop 7 through a fixed field stop 5. Although FIG. 3 arranges the field stop 5 closer to the condenser lens 4 than the mobile blind 7, the field stop 5 may be located at the side of the relay lens system 8.

The field stop 5 forms a rectangular slit shaped opening, and allows a beam that has passed through the field stop 5 to have a rectangular slit shaped section, and then enter the relay lens system 8. The longitudinal direction of the slit is a direction perpendicular to the paper. The relay lens system 8 is a lens system that maintains the mobile blind 7 conjugate with the pattern surface on the reticle R. It includes two blades or light shielding plates 7A and 7B that define a width in a scan direction or direction X, which will be described later, and two blades (not shown) that define a width in a non-scan direction perpendicular to the scan direction. The blades 7A and 7B that define the width in the scan direction are supported by drive parts 6A and 6B, respectively, so that they may move in the scan direction independently, whereas two blades (not shown) that define the width in the non-scan direction are also independently movably supported. The instant embodiment irradiates the illumination light only to a desired exposure area defined by the mobile blind 7 in the slit shaped illumination area 21 on the reticle R, which has been set by the fixed field stop 5. The relay lens system 8 is a bilateral telecentric optical system that maintains telecentricity of the slit shaped illumination area 21 on the reticle R.

The reticle R is held on a reticle stage RST. An interferometer 22 detects a position of the reticle stage RST, and a reticle-stage drive part 10 drives the reticle stage RST. An optical element G1 is held below the reticle R, and scanned with the reticle R when the reticle stage RST is scan-driven. The circuit pattern image on the reticle R, which is defined by the mobile blind 7 in the slit shaped illumination area 21, is projected and exposed onto the wafer W through the projection optical system 13.

It is assumed that a direction +X or −X is a scan direction of the reticle R with respect to the slit shaped illumination area 21 and a direction Z is a direction horizontal to the optical axis of the projection optical system 13 in a two-dimensional plane perpendicular to the optical axis of the projection optical system 13.

In this case, the reticle stage RST is driven by the reticle-stage drive part 10 to scan the reticle R in the scan direction, i.e., direction +X or −X, and a mobile-blind control part 11 controls actions of the drive parts 6A and 6B for the mobile blind 7 and the drive parts for the non-scan direction. A main control system 12 that controls operations of the entire device controls the reticle-stage drive part 10 and the mobile-blind control part 11.

A reticle surface position detection system RO is formed between the optical element G1 held by the reticle stage RST and the projection optical system 13.

A wafer W is carried by the wafer feed unit and held on the wafer stage WST, which positions the wafer W in a plane perpendicular to the optical axis of the projection optical system 13, and includes an XY stage that scans the wafer W in the directions ±X, a Z stage that positions the wafer W in the direction Z, etc. An interferometer 23 detects a position of the wafer stage WST. An off-axis alignment sensor 16 is formed above the wafer W. The alignment sensor 16 detects an alignment mark on the wafer W, and a control part 17 processes the detection result, and feeds the processed data to the main control system 12. The main control system 12 controls positioning and scanning of the wafer stage WST through the wafer stage drive part 15.

In exposing a pattern image on the reticle R onto each shot area on the wafer W through the projection optical system 13 in a scan exposure manner, the reticle R is scanned at a speed VR in the direction −X or +X relative to the slit shaped illumination area 21 that is defined by the field stop 5 in FIG. 3. The wafer W is scanned at a speed VW (=β·VR) in synchronization with scanning of the reticle R in the direction +X (or −X) where β is a projection magnification of the projection optical system 13. Thereby, the circuit pattern image on the reticle R is sequentially transferred on the shot areas on the wafer W.

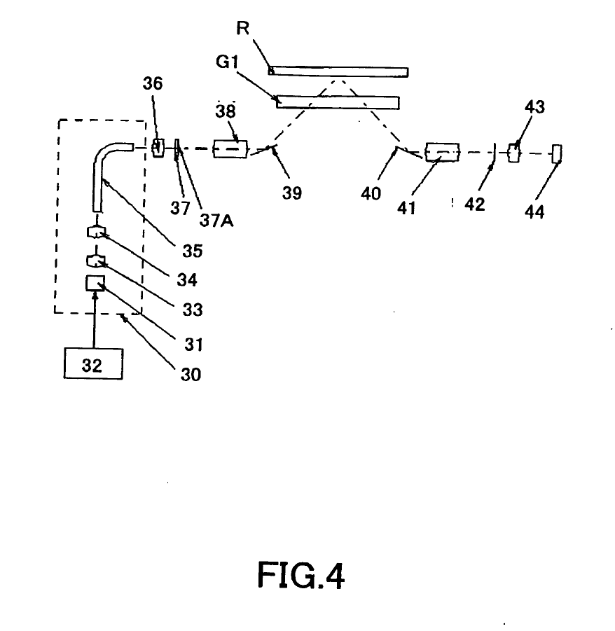

Referring now to FIG. 4, a description will be given of the reticle surface position detection system RO. Initially, a description will be given of a basic measurement principal of the reticle surface position detection system. The light is obliquely irradiated onto the reticle pattern surface as a surface to be detected, a position detection element detects an incident position to a predetermined surface of the light that has reflected on the surface to be detected, and the positional information is used to detect the positional information in the direction Z of the surface to be detected (or the optical-axis direction of the projection optical system 13). While FIG. 4 illustrates only one system, plural beams that have been set in the direction approximately orthogonal to the scan direction are projected to plural measurement points on the surface to be detected, and the positional information in the direction Z, which has been obtained at each measurement point is used to calculate inclination information of the surface to be detected. Positional information in the direction Z may be measured in the scan direction from plural measurement points by scanning the reticle R. These pieces of positional information may be used to calculate a surface shape of the pattern surface on the reticle R.

A description will now be given of each element in the reticle surface position detection system. In FIG. 4, 30 is a light source part in the reticle surface position detection system. 31 is a light source in the reticle surface position detection system. The light source 31 may use an LED that emits infrared light with a peak wavelength of about 740 to 850 nm in order to obtain a sufficient amount of reflected light from the reticle material in response to an oblique incidence. 32 is a drive-circuit that is adapted to adequately control the intensity of light emitted from the light source 31.

The light emitted from the light source 31 is guided to an optical transmission means 35, such as an optical fiber, through a collimator lens 33 and a condenser lens 34.

The light from the optical transmission means 35 illuminates a slit 37 through an illumination lens 36. The slit 37 forms a surface position measurement mark 37A for the pattern surface on the reticle R, and the mark 37A is projected onto the pattern surface through the mirror 39 on the reticle R as a surface to be detected. An imaging lens 38 maintains the pattern surface on the reticle R optically conjugate with the slit 37. FIG. 4 illustrates a principal ray for description convenience. The light from a mark image that has imaged on the pattern surface on the reticle R is reflected on the pattern surface on the reticle R, and forms a mark image again on the re-imaging position 42 through a mirror 40 and imaging lens 41. The light from the mark image that has re-imaged at a re-imaging position 42 is condensed by an enlargement optical system 43, and approximately forms an image on a light-receiving element 44 for detecting a position. A signal from the light-receiving element 44 is processed by the reticle surface position signal processing system (not shown) and processed as information on the inclination and the direction Z of the pattern surface on the reticle R as a surface to be detected.

While FIG. 4 illustrates a sectional view and thus only one system, plural systems may be arranged actually. In addition, while FIG. 4 shows a direction of the detection light of the reticle surface position detection system incident on the pattern surface on the reticle R in a direction parallel to the scan direction, the configuration may employ a direction orthogonal to the scan direction or an incidence at an arbitrary angle.

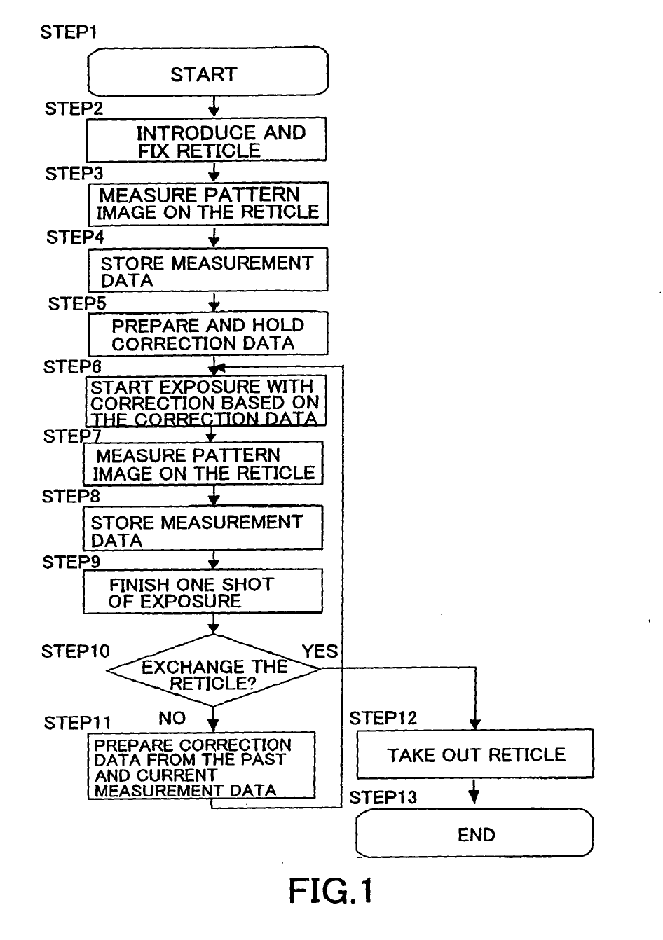

Next follows a description of an overview of a scan exposure method of a first embodiment according to the present invention, with reference to a flowchart shown in FIG. 1.

Step 1 receives a start command, and Step 2 introduces the reticle R into and fixes the reticle R onto the reticle stage RST through a reticle feed unit (not shown).

In advance to exposure, Step 3 detects plural surface positions on the pattern surface on the reticle R by previously scanning the exposure area on the pattern surface on the reticle R. An actual detection in the exposure area may provide a proper correction, e.g., to displacements in the optical-axis direction associated with the movements of the reticle stage RST. The detections in both scan directions enable the correction to cover different displacements in the optical-axis direction associated with the movement of the reticle stage RST in the both scan directions. An average value is obtained from deviated detection results for each scan of the reticle stage RST as a result of repetitive detections plural times. The scan speed for the detection may be the same scan speed for exposure, or lower than the scan speed for exposure in order to detects more points in the scan directions.

Step 4 stores the detected values of the pattern surface of the reticle in a memory means.

Based on the detected value of the pattern surface on the reticle R that has been stored in Step 4, Step 5 calculates a lens drive correction value, a wavelength correction value of the projection light, and a positional correction value of the wafer w relative to the projection optical system 13 and stores the correction data in order to realize an optical characteristic of the projection optical system 13 suitable for the optimal exposure result in the scan exposure. When the light that has been emitted by the light source 31 and passed through the slit 37 hits an interference between chrome and glass on the pattern surface on the reticle R, the light that enters the light-receiving element 44 causes an measurement error since the light disturbs due to the different reflective index between chrome and glass. In order to reduce the disturbance, an approximate surface is calculated from multiple detection points, and correction values are calculated based on the approximate surface.

Step 6 starts a scan exposure when the correction values have been calculated. The correction data that has been obtained prior to the exposure is used for the first scan exposure.

Step 7 aligns the exposed area on the wafer with the exposure image plane based on the correction value obtained in Step 5, and detects plural surface positions on the pattern surface on the reticle R. Step 8 stores, in the memory means, the detection values of the pattern surface on the reticle R, which have been detected during the exposure.

After Step 9 finishes exposure for one shot, Step 10 determines whether the reticle R is to be exchanged. When the same reticle R is used continuously for the scan exposure, the detection values of the pattern surface on the reticle R which have been stored in Step 8 and those obtain in the past are used to calculate a lens drive correction value, a wavelength correction value of the projection light, and a positional correction value of the wafer W relative to the projection optical system 13 in order to realize an optical characteristic of the projection optical system 13 suitable for the optimal exposure result in the scan exposure. This may provide a correction even to a deformation of the reticle R due to the illumination light after the exposure starts. The correction value is calculated every scan direction to handle a distortion in the optical-axis direction of the illumination light for exposure associated with the movements of the reticle stage RST in the scan direction.

When Step 10 determines that the reticle R is to be exchanged, Step 12 takes out the reticle R.

Step 11 updates the correction data based on the past detection data and current detection data, and returns to Step 6. Step 6 exposes using the updated correction data.

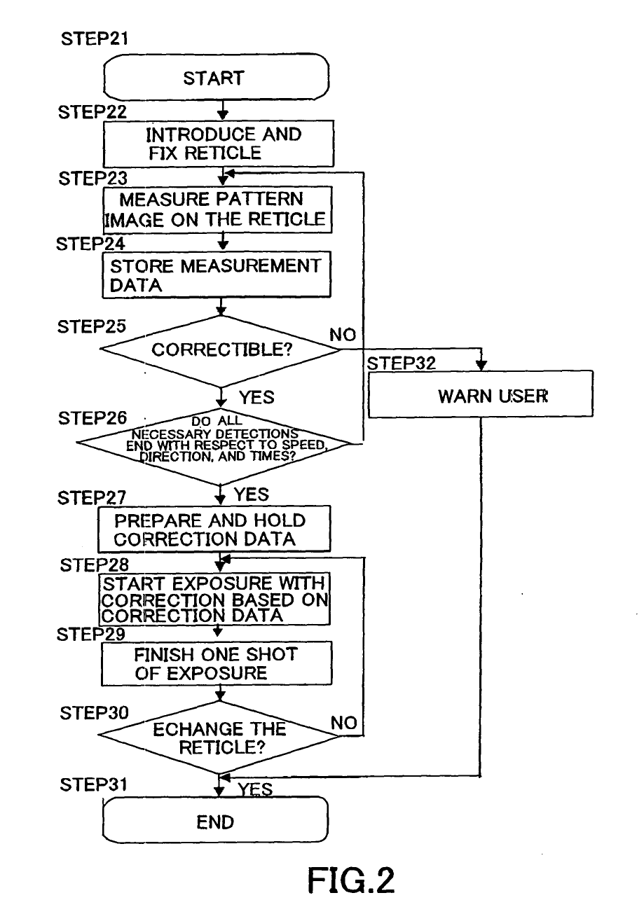

Next follows a description of an overview of a scan exposure method of another embodiment according to the present invention, with reference to a flowchart shown in FIG. 2.

Step 21 receives a start command, and Step 22 introduces the reticle R into and fixes the reticle R onto the reticle stage RST through a reticle feed means (not shown).

In advance to exposure, Step 23 detects plural surface positions on the pattern surface on the reticle R by previously scanning the exposure area on the pattern surface on the reticle R. An actual detection in the exposure area may provide a proper correction, e.g., to displacements in the optical-axis direction associated with the movements of the reticle stage RST. The detections in both scan directions enable the correction to cover different displacements in the optical-axis direction associated with the movement of the reticle stage RST in the both scan directions. An average value is obtained from deviated detection results for each scan of the reticle stage RST as a result of repetitive detections plural times. The scan speed for the detection may be the same scan speed for exposure, or lower than the scan speed for exposure in order to detects more points in the scan directions.

Step 24 stores the detected values of the pattern surface of the reticle in the memory means.

Based on the detected value of the pattern surface on the reticle R that has been stored in Step 24, Step 25 calculates a lens drive correction value, a wavelength correction value of the projection light, and a positional correction value of the wafer W relative to the projection optical system 13, in order to realize an optical characteristic of the projection optical system 13 suitable for the optimal exposure result in the scan exposure. When the apparatus cannot provide these corrections, the reticle R is taken out, introduced and fixed again, and a pattern surface of the reticle R is detected. This action may possibly eliminate dust between the reticle R and the reticle holder (not shown) when the reticle R is absorbed and held by the reticle holder, and improve a condition of the absorptive holding. This may be repeated several times. If these actions cannot enable the apparatus to provide the correction, Step 32 warns the user and ends the exposure. This may call user's early attention and prevent improper exposure, for example, where dust is held between the reticle R and the reticle holder when the reticle R is absorbed and held by the reticle holder.

In addition, a special detection means for detecting dust is unnecessary to be newly provided. If the correction is available, Step 26 determines whether the detections have ended for necessary speed, direction and times. If not, the procedure is fed back to Step 23, and a necessary detection is achieved.

When the detections have ended, Step 27 calculates a lens drive correction value, a wavelength correction value of the projection light, and a positional correction value of the wafer W relative to the projection optical system 13, and prepares and stores the correction data in order to realize an optical characteristic of the projection optical system 13 suitable for the optimal exposure result in the scan exposure. Step 28 starts the scan exposure when the correction values have been calculated.

After Step 29 finishes exposure for one shot, Step 30 determines whether the reticle R is to be exchanged. When the same reticle R is used continuously for the scan exposure, the procedure is fed back to Step 28 to continue the scan exposure. Otherwise, the procedure ends at Step 31.

Thus, the present invention may detect a deflection of the reticle R resulting from the thermal deformation during exposure and a difference in deformation amount of the surface shape on the reticle R after the reticle R is exchanged, absorbed and held. The correction amount is operated and corrected based on the detection result. A correction to the distortion and the like that would otherwise occur on the reticle's pattern surface may advantageously prevent a curved pattern image and provide an accurate and stable image of the reticle pattern.

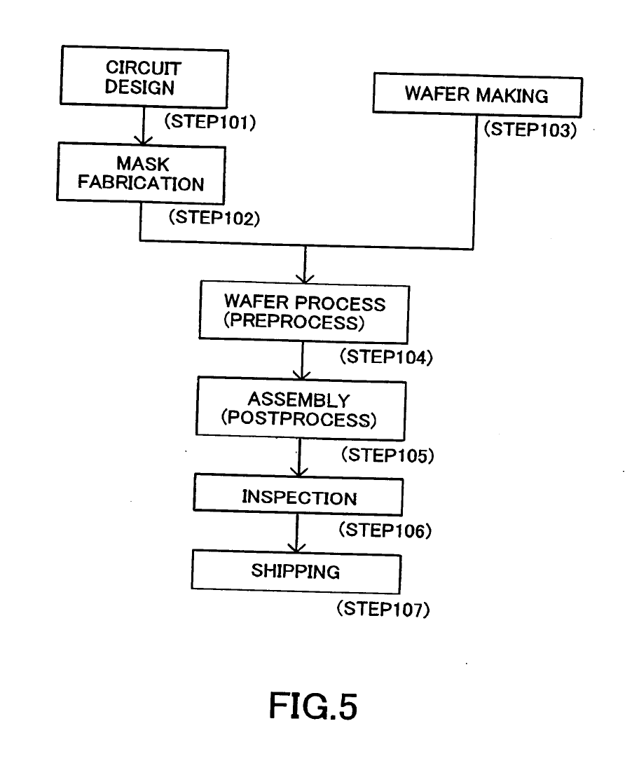

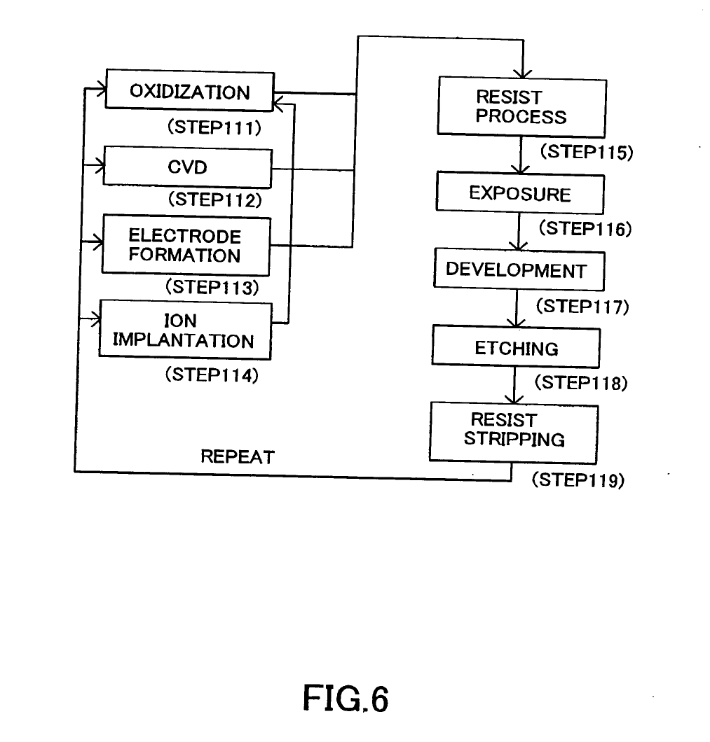

Referring now to FIGS. 5 and 6, a description will be given of an embodiment of a device fabrication method using the above mentioned scan exposure apparatus. FIG. 5 is a flowchart for explaining how to fabricate devices (i.e., semiconductor chips such as IC and LSI, LCDs, CCDs, and the like). Here, a description will be given of the fabrication of a semiconductor chip as an example. Step 101 (circuit design) designs a semiconductor device circuit. Step 102 (mask fabrication) forms a mask having a designed circuit pattern. Step 103 (wafer making) manufactures a wafer using materials such as silicon. Step 104 (wafer process), which is also referred to as a pretreatment, forms actual circuitry on the wafer through lithography using the mask and wafer. Step 105 (assembly), which is also referred to as a post-treatment, forms into a semiconductor chip the wafer formed in Step 104 and includes an assembly step (e.g., dicing, bonding), a packaging step (chip sealing), and the like. Step 106 (inspection) performs various tests for the semiconductor device made in Step 105, such as a validity test and a durability test. Through these steps, a semiconductor device is finished and shipped (Step 107).

FIG. 6 is a detailed flowchart of the wafer process in Step 104 in FIG. 5. Step 111 (oxidation) oxidizes the wafer's surface. Step 112 (CVD) forms an insulating film on the wafer's surface. Step 113 (electrode formation) forms electrodes on the wafer by vapor disposition and the like. Step 114 (ion implantation) implants ion into the wafer. Step 115 (resist process) applies a photosensitive material onto the wafer. Step 116 (exposure) uses the above exposure apparatus to expose a circuit pattern on the mask onto the wafer. Step 117 (development) develops the exposed wafer. Step 118 (etching) etches parts other than a developed resist image. Step 119 (resist stripping) removes disused resist after etching. These steps are repeated, and multi-layer circuit patterns are formed on the wafer. Use of the fabrication method in this embodiment helps fabricate higher-quality devices than ever.

Further, the present invention is not limited to these preferred embodiments and various variations and modifications may be made without departing from the scope of the present invention.

Thus, the instant embodiments may provide an exposure method and apparatus, which easily improve reliability of a correction to an optical characteristic of the projection optical system, or a position of a wafer relative to the projection optical system.

1. An exposure method for exposing a pattern image formed on a reticle onto a plate through a projection optical system by synchronously scanning the reticle and the plate, said exposure method comprising the steps of:
measuring a surface shape of the reticle at a position to be exposed, and holding the surface shape as correction data;
controlling a synchronous scan based on the correction data; and
updating the correction data by repeating measurements of the surface shape of the reticle.

2. An exposure method according to claim 1, wherein said controlling step corrects an optical characteristic of the projection optical system.

3. An exposure method according to claim 1, wherein said controlling step corrects a position of the plate relative to the projection optical system.

4. An exposure method according to claim 1, wherein said updating step measures the surface shape of the reticle during exposure.

5. An exposure method according to claim 1, wherein said updating step updates the correction data whenever an exposure for one shot ends.

6. An exposure method according to claim 1, wherein said measuring and holding step measures the surface shape of the reticle at a position to be exposed in a scan direction.

7. An exposure method according to claim 1, wherein said measuring and holding step prepares the correction data from an average of plural measurements that have been conducted at positions to be exposed.

8. An exposure method according to claim 1, wherein said measuring and holding step measures plural times at the same speed and in the same direction.

9. An exposure method according to claim 1, wherein the surface shape of the reticle is measured by measuring a pattern surface of the reticle relative to the projection optical system.

10. An exposure apparatus for exposing a pattern image formed on a reticle onto a plate by synchronously scanning the reticle and the plate, said exposure apparatus comprising:
a projection optical system for protecting the pattern image onto the plate;
a measurement unit for measuring a surface shape of the reticle at a position to be exposed and for holding the surface shape as correction data, said measurement unit updating the correction data by repeating measurements of the surface shape of the reticle; and
a controller for controlling a synchronous scan based on the correction data.

11. A device fabrication method of the present invention comprising the steps of:
exposing a pattern on a reticle, onto an object by using an exposure apparatus; and
performing a predetermined process for the exposed object,
wherein the exposure apparatus for exposing a pattern image formed on a reticle onto a plate by synchronously scanning the reticle and the plate includes a projection optical system that projects the pattern image onto the plate, a measurement unit for measuring a surface shape of the reticle at a position to be exposed and for holding the surface shape as correction data, said measurement unit updating the correction data by repeating measurements of the surface shape of the reticle, and a controller for controlling a synchronous scan based on the correction data.
